(19) United States
(12) Patent Application Publication
(10) Pub. No.: US 2026/0093001 A1
(43) Pub. Date: Apr. 2, 2026

(54) MAGNETIC RESONANCE IMAGING APPARATUS AND MAGNETIC RESONANCE IMAGE GENERATION METHOD

(71) Applicant: FUJIFILM Corporation, Tokyo (JP)

(72) Inventor: Hiroki SHOJI, Tokyo (JP)

(73) Assignee: FUJIFILM Corporation, Tokyo (JP)

(21) Appl. No.: 19/347,327

(22) Filed: Oct. 1, 2025

(30) Foreign Application Priority Data
Oct. 2, 2024 (JP) 2024-173841

(51) Int. Cl. G01R 33/565; G01R 33/56

(52) U.S. Cl. CPC G01R 33/56509; G01R 33/5608

(57) ABSTRACT

Accuracy in a case where body motion correction reconstruction is performed in response to body motion that occurs during imaging by an MRI apparatus is improved, and accuracy of a body motion-corrected image is improved.

In a case where k-space data consisting of nuclear magnetic resonance signals is collected using an MRI apparatus, a strength of body motion correction is varied according to a position in k-space of measurement data affected by body motion that has occurred. In one aspect, in a case of determining whether measurement data acquired at a time of body motion detection is data affected by the body motion, a value of a threshold value used for body motion determination is varied according to a position in k-space of the measurement data. In another aspect, upon performing body motion correction reconstruction including iterative calculation, the body motion correction reconstruction is performed by varying a weight of processing or the like according to a position in k-space of data affected by the body motion, in a case where the data affected by body motion is incorporated into the iterative calculation as an initial value of the iterative calculation without excluding the data affected by the body motion, or during an iterative calculation process.

### CROSS-REFERENCE TO RELATED APPLICATIONS

The present application claims priority under 35 U.S.C. § 119 to Japanese Patent Application No. 2024-173841, filed Oct. 2, 2024. Each of the above application(s) is hereby expressly incorporated by reference, in its entirety, into the present application.

### BACKGROUND OF THE INVENTION

### 1. Field of the Invention

The present invention relates to a magnetic resonance imaging apparatus (hereinafter, referred to as an MRI apparatus), and more particularly, to a technique for reducing an influence of body motion that occurs in a subject during imaging.

### 2. Description of the Related Art

An MRI apparatus can non-invasively grasp an internal tissue of a subject to be examined and is widely utilized in medical settings. One of the problems in obtaining a high-quality image with an MRI apparatus is body motion of the subject during imaging. Body motion of the subject includes motion associated with respiration and heartbeat, and unintentional motion not related thereto, such as motion associated with physiological reactions including convulsions, sneezing, and coughing, and other sudden motions, for example. Such body motion causes artifacts in the image, and the resulting deterioration in image quality hinders image diagnosis.

Conventionally, various techniques have been proposed to reduce deterioration in image quality caused by body motion. In dealing with body motion, important processes include detecting body motion of the subject during imaging and processing data collected at the time the body motion is detected. In the MRI apparatus, detecting body motion that occurs while k-space data is being collected is a problem. Methods have been proposed, such as a method of collecting nuclear magnetic resonance signals (referred to as navigator echoes) for detecting body motion in parallel with the collection of k-space data for image reconstruction, and detecting body motion from the navigator echoes (for example, JP1994-047021A (JP-H06-047021A); a method of installing devices such as a pressure sensor or an abdominal pressure gauge to mainly detect respiratory motion; and a method of installing a surveillance camera in an imaging space where a subject is placed, and detecting body motion by analyzing frame images from the camera (JP2023-027608A). JP1994-047021A (JP-H06-047021A) discloses that k-space is divided into two or more blocks, and body motion is detected for each block using different body motion detection means (one of which is a navigator echo).

As processing on the data collected in a case where body motion is detected (hereinafter, referred to as “body motion-affected data”), there are methods such as a method of performing phase correction on the body motion-affected data using phase information obtained from navigator echoes (JP1994-047021A (JP-H06-047021A)), and a method of performing reconstruction by zero-substituting a signal at a position where body motion has occurred, or performing reconstruction by estimating the body motion-affected data through iterative calculation or the like (such as JP2023-022669A).

### SUMMARY OF THE INVENTION

In conventional body motion processing, there are examples in which body motion processing is performed in consideration of differences in body motion levels depending on a region or a site of the subject. However, there may be various factors other than the body motion level that affect the image due to body motion. Therefore, conventional methods may excessively remove measurement data having a relatively small influence on the image, or may fail to appropriately remove measurement data having a large influence on the image. In such a case, problems such as insufficient removal of body motion artifacts or image blurring may occur.

For example, JP1994-047021A (JP-H06-047021A) discloses that image data is divided into a region with a relatively large magnitude of body motion and a region with a relatively small magnitude of body motion, and each region is transformed into measurement space data, followed by different phase corrections for the measurement data of each region. However, although this allows for body motion correction that takes into account the magnitude of body motion, it cannot solve the above-mentioned problems.

An object of the present invention is to improve accuracy of body motion processing by performing processing in consideration of regions of k-space in the body motion processing.

In order to achieve the above-described object, according to the present invention, in a case where k-space data consisting of nuclear magnetic resonance signals is collected using an MRI apparatus, a strength of body motion correction is varied according to a position in k-space of measurement data affected by body motion that has occurred. In one aspect, in a case of determining whether measurement data acquired at a time of body motion detection is data affected by the body motion, a value of a threshold value used for body motion determination is varied according to a position in k-space of the measurement data. Specifically, the threshold value is set such that body motion determination is stricter in a low-frequency region of the k-space and body motion determination is more lenient in a high-frequency region.

In another aspect, upon performing body motion correction reconstruction including iterative calculation, the body motion correction reconstruction is performed to reduce an influence of body motion by varying a weight of processing or the like according to a position in k-space of data affected by the body motion, in a case where the data affected by body motion is incorporated into the iterative calculation as an initial value of the iterative calculation without excluding the data affected by the body motion, or during an iterative calculation process.

That is, according to a first aspect of the present invention, there is provided an MRI apparatus comprising: an imaging unit configured to collect k-space data consisting of magnetic resonance signals; and a processor configured to generate an image using the k-space data and analyze body motion of a subject during imaging. The processor is configured to: detect the body motion of the subject during imaging by using information from an optical imaging device that optically images the subject during imaging or the magnetic resonance signals obtained by the imaging unit; and specify, in the k-space data, data affected by the body motion as body motion-affected data, and, during the specification, vary a threshold value used to determine whether or not data as a determination target is the body motion-affected data, depending on a position in k-space of the data.

In addition, according to a second aspect of the present invention, there is provided an MRI apparatus, in which the processor is configured to: detect the body motion of the subject during imaging by using information from an optical imaging device that optically images the subject during imaging or the magnetic resonance signals obtained by the imaging unit; specify, in the k-space data, data affected by the body motion as body motion-affected data, and perform body motion correction reconstruction including iterative calculation by using the k-space data including the body motion-affected data; and perform processing of reducing an influence of the body motion on the body motion-affected data in the body motion correction reconstruction.

Further, according to the present invention, there is provided a method of generating an image with body motion correction by using k-space data acquired by a magnetic resonance imaging apparatus, the k-space data including, as accessory information, body motion information in a case where the k-space data is acquired.

A magnetic resonance image generation method according to a first aspect of the present invention comprises: specifying, in the k-space data, body motion-affected data affected by body motion by using the body motion information; and, during the specification, varying a threshold value related to the body motion and used to determine the body motion-affected data, depending on a position in k-space.

A magnetic resonance image generation method according to a second aspect of the present invention comprises specifying, in the k-space data, data affected by body motion as body motion-affected data, and performing body motion correction reconstruction including iterative calculation by using the k-space data including the body motion-affected data; and, during the body motion correction reconstruction, performing a smoothing process on the body motion-affected data, and then using, as an initial value of the iterative calculation, an image obtained by transforming, into image space, the k-space data including the body motion-affected data after the smoothing process.

According to the first aspect of the present invention, by changing the threshold value for body motion detection depending on whether the measurement data collected at the time of body motion occurrence is low-frequency region data or high-frequency region data in the k-space, it is possible to prevent insufficient removal or excessive removal of body motion-affected data, thereby preventing insufficient removal of body motion artifacts or, conversely, image blurring due to excessive removal, and enabling highly accurate body motion correction.

Additionally, according to the second aspect of the present invention, it is possible to include, in the body motion correction reconstruction including iterative calculation, processing of reducing the weight of the body motion-affected data, thereby enabling effective body motion removal while reducing a cost of the iterative calculation.

### BRIEF DESCRIPTION OF THE DRAWINGS

FIG. 1 is a diagram showing an overall outline of an MRI apparatus to which the present invention is applied.

FIG. 2 is a flowchart showing an outline of processing of a processor.

FIG. 3 is a flowchart showing a flow of processing of Embodiment 1.

FIG. 4 is a diagram illustrating regions of k-space.

FIG. 5 is a graph showing a relationship between a position in k-space and a threshold value.

FIG. 6 is a diagram showing a relationship between body motion information and a pulse sequence.

FIG. 7 is a diagram showing an example of body motion correction reconstruction by a processor (image generation unit) of Embodiment 1.

FIG. 8 is a diagram illustrating smoothing of body motion-affected data.

FIG. 9 is a diagram showing a flow of processing of a modification example of Embodiment 1.

### DESCRIPTION OF THE PREFERRED EMBODIMENTS

Embodiments of the present invention will be described below with reference to the drawings.

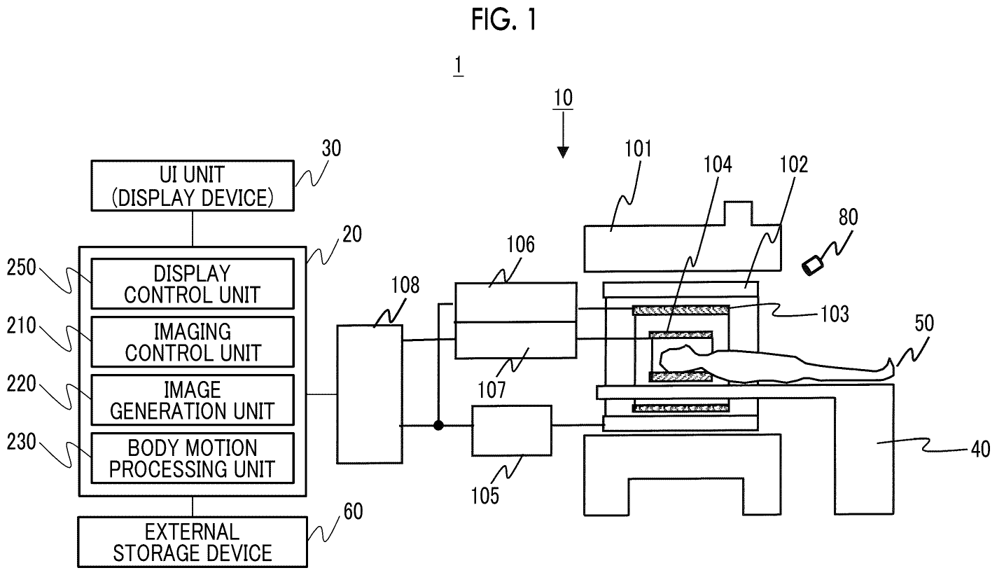

First, an overall outline of an MRI apparatus to which the present invention is applied will be described. As shown in FIG. 1, an MRI apparatus 1 includes an imaging unit 10 that causes nuclear magnetic resonance in atomic nuclei of atoms constituting tissues of a subject 50 to collect nuclear magnetic resonance signals generated from the subject; a processor 20 that processes the nuclear magnetic resonance signals collected by the imaging unit 10 and that controls the imaging unit 10; and a user interface unit (hereinafter, referred to as a UI unit) 30 that allows an operator of the MRI apparatus 1 (hereinafter, referred to as a user), such as a doctor or a technologist, to set imaging conditions, input commands necessary for processing, and display images obtained by the MRI apparatus 1 and GUI. In addition, the MRI apparatus 1 may comprise an external storage device 60 that stores the generated images and other information, and an interface (not shown) that communicates with an external device.

The configuration of the imaging unit 10 is the same as the configuration of a known MRI apparatus, and includes a static magnetic field magnet 101 that generates a uniform static magnetic field in an examination space where the subject 50 is placed, a gradient magnetic field coil 102 that applies a magnetic field gradient to the static magnetic field, an RF transmit coil 103 that applies a predetermined radio frequency magnetic field to the subject, and an RF receive coil 104 that receives a nuclear magnetic resonance signal (hereinafter, also referred to as an echo signal) generated from the subject. The gradient magnetic field coil 102 is connected to a gradient magnetic field power supply 105, the RF transmit coil 103 is connected to an RF transmission unit 106 including an RF oscillator, an RF amplifier, and the like, and the RF receive coil 104 is connected to an RF reception unit 107 provided with a QD detector and an AD converter. Note that the RF transmit coil 103 and the RF receive coil 104 may be combined into a single RF coil; however, generally, the RF transmit coil 103 is housed within a gantry (not shown) together with the static magnetic field magnet 101 and the gradient magnetic field coil 102 so as to surround the examination space, and the RF receive coil 104 is disposed in the examination space in a state of being attached to the subject 50.

The imaging unit 10 further comprises a sequencer 108 that operates the RF transmission unit 106, the gradient magnetic field power supply 105, and the RF reception unit 107 described above in accordance with a predetermined pulse sequence, and imaging is performed in accordance with an imaging sequence set in the sequencer 108. The operation related to imaging is the same as that of a general MRI apparatus, and in the present specification, descriptions other than the processing related to the invention are omitted.

The imaging unit 10 further comprises a bed device 40 for placing the subject thereon. Additionally, one or a plurality of surveillance cameras 80 for monitoring the subject are installed inside the gantry or at an end portion of an opening. In such a case, the surveillance camera 80 can also function as body motion detection means for detecting body motion of the subject.

The processor 20 controls the imaging unit 10, performs signal processing, various calculations, and the like on the nuclear magnetic resonance signals collected by the imaging unit 10, and, as mentioned above, performs processing (body motion processing) to reduce the influence of body motion that occurs in the subject during imaging. For example, the processor 20 captures video from the surveillance camera 80, monitors the occurrence of body motion, and, based on information at the time of body motion occurrence, applies a timestamp corresponding to the body motion to measurement data being collected at that time, and performs processing such as body motion correction.

In order to achieve the above-described processing, the processor 20 includes an imaging control unit 210 that controls imaging, a display control unit 250 that controls display in the UI unit 30, an image generation unit 220 that performs various calculations related to image generation such as image reconstruction, and a body motion processing unit 230 that processes body motion of the subject 50 during imaging.

Although the processor 20 is shown as a single block in FIG. 1, the processor 20 may be configured by one or a plurality of hardware components, or a combination of hardware and programs. The type of hardware is not limited, and, for example, the processor may be configured by hardware such as a central processing unit (CPU), a micro processing unit (MPU), a programmable logic device such as a field programmable gate array (FPGA), a dedicated circuit for executing specific processing such as an application specific integrated circuit (ASIC), a graphic processing unit (GPU) or a neural processing unit (NPU). Additionally, the type of hardware may be a combination of different types of hardware. In a case where a plurality of hardware components are configured to execute one or a plurality of processes of a certain processor, the plurality of hardware components may be present in physically separate devices or may be present within the same device.

In a case where the processor 20 is implemented by a combination of hardware and programs, the program may be software such as firmware or a microcode. The program may also be, for example, a group of program modules, and each function may be implemented by a processor configured to execute the corresponding function. The program may be a program code or a plurality of code segments that are stored in one or a plurality of non-transitory computer-readable media (for example, storage media or other storages).

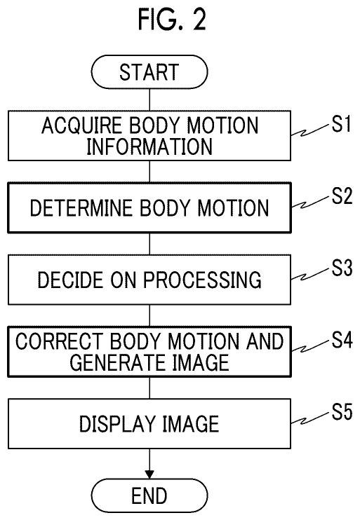

Based on the above configuration, an outline of the processing of the MRI apparatus 1 of the present embodiment will be described. FIG. 2 shows a flow of the processing.

First, in a case where imaging is started under the control of the imaging control unit 210, the body motion processing unit 230 acquires body motion information detected by the body motion detection means such as the surveillance camera 80 (S1) and determines whether body motion that affects the image has occurred, by using a threshold value (S2). Whether the body motion affects the image depends on the level and duration of the body motion, as well as the position in k-space of the measurement data acquired at the time of body motion occurrence. In the present embodiment, the body motion level is determined using a threshold value that varies depending on the position in k-space of the measurement data, and it is determined whether or not the measurement data is measurement data that affects the image (body motion-affected data).

As the threshold value for body motion determination, a reference body motion level threshold value may be determined in advance for each site, or a reference body motion level threshold value may be determined based on the body motion level of each patient or each site of the patient obtained in a preliminary measurement and the reference threshold value may be adjusted according to the position in k-space at the time of application in body motion determination. Alternatively, a reference threshold value may be set in advance according to the position in k-space and stored in a memory, for example, as a table or a function, and the threshold value may be read out and used at the time of application.

In a case where the body motion-affected data is specified in the body motion determination, subsequent processing is determined (S3) based on factors such as the position in k-space of the body motion-affected data and the number of pieces of body motion-affected data. The subsequent processing includes body motion correction reconstruction including, for example, re-measurement, removal of body motion-affected data, correction, zero substitution, and the like, and a determination is made as to which processing of these is to be executed. For the processing, a determination criterion is set in advance, and the processing can be selected based on the criterion.

Subsequently, imaging or image reconstruction is performed in accordance with the decided-on processing, and in a case where the measurement data necessary for image reconstruction is finally collected, the image generation unit 220 performs the image reconstruction (S4). In a case where one or more pieces of body motion-affected data have been specified, the image reconstruction includes image reconstruction with body motion correction (body motion correction reconstruction). In a case where the body motion correction reconstruction is performed, the image generation unit 220 may employ a method that takes into account the position in k-space of the body motion-affected data. For example, in a case where the iterative calculation is performed as the body motion correction reconstruction, the weight used in the calculation may be varied according to the position in k-space of the measurement data. The image generated by the image generation unit 220 is displayed on a display device or the like of the UI unit 30 by the display control unit 250 together with accessory information such as subject information and imaging conditions (S5). In addition, the image is transferred to an external storage device or an external device other than the MRI apparatus 1 as necessary.

With the MRI apparatus of the present embodiment, by adjusting the threshold value used for the body motion determination according to the position in k-space of the measurement data measured in a case where the body motion is detected, it is possible to enhance the accuracy of specifying the body motion-affected data. As a result, it is possible to prevent excessive or insufficient body motion correction and provide a body motion-corrected image with high image quality in a time-efficient manner.

Hereinafter, among the processes of the MRI apparatus of the present embodiment, specific embodiments will be described, focusing on threshold value setting that takes into account the k-space position and body motion correction reconstruction that takes into account the k-space position.

### Embodiment 1

In the present embodiment, in threshold value setting, adjustment corresponding to the k-space position of the measurement data is made, and reconstruction by iterative calculation is performed as the body motion correction reconstruction method. In this case, a case will be described in which weighting corresponding to the k-space position is performed in data consistency processing.

### Embodiment of Threshold Value Setting

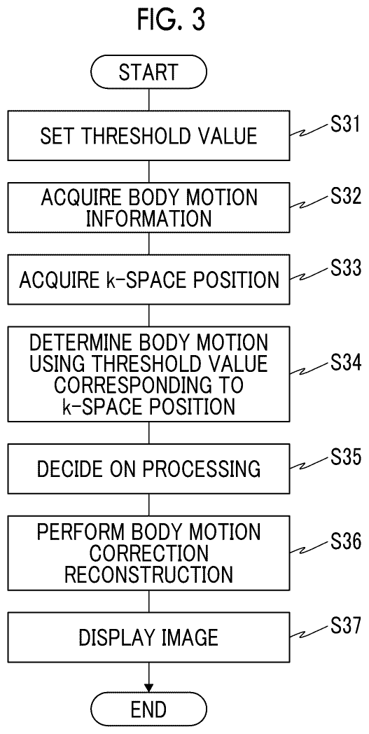

First, a flow of processing of an embodiment related to threshold value setting is shown in FIG. 3.

First, a reference threshold value is set in advance (S31). The threshold value is determined based on the magnitude of the body motion level that affects the image, and the extent to which body motion level affects the image varies depending on factors such as the imaging site and the resolution of the image. Therefore, as a simplified approach, a predetermined threshold value can be set in advance for each site according to the expected image quality. In addition, in a preliminary measurement (such as imaging for deciding on imaging cross sections or imaging conditions) performed on the subject prior to the main imaging (imaging for acquiring a subject image), body motion characteristics for each subject may be obtained, and based on the body motion characteristics, a threshold value may be set for each subject, and, as necessary, threshold value may further be set for each site of the subject.

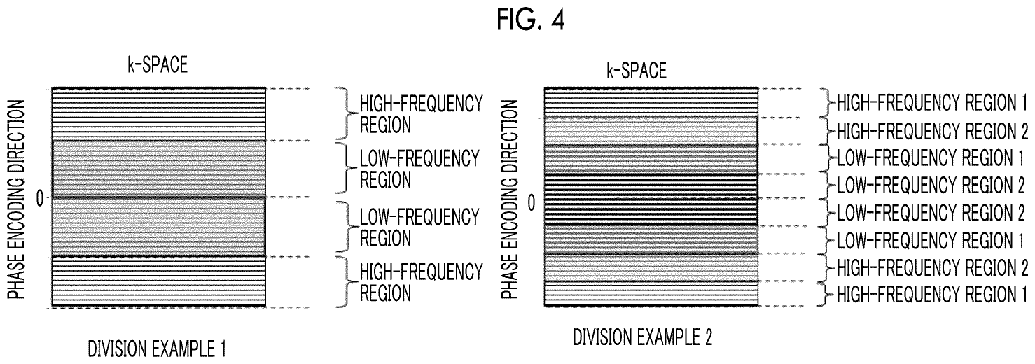

A threshold value corresponding to the k-space position is set based on the reference threshold value set in this manner. The threshold value setting corresponding to the k-space position is basically based on the idea of making body motion determination stricter in the low-frequency region of k-space and body motion determination more lenient in the high-frequency region. Specifically, for example, k-space is divided into a low-frequency region and a high-frequency region, and the threshold value is set to be lower in the low-frequency region and the threshold value to be higher in the high-frequency region. FIG. 4 shows a division example of k-space. Division Example 1 shown on the left side of FIG. 4 is a case where the region of k-space divided above and below the origin (zero encoding) is divided into a low-frequency region and a high-frequency region, and different values are set for the threshold value for the low-frequency region and the threshold value for the high-frequency region (the threshold value for the low-frequency region <the threshold value for the high-frequency region). Division Example 2 shown on the right side of FIG. 4 is a case where the low-frequency region and the high-frequency region are further divided, and the threshold values are set to increase in the order of a low-frequency region 2, a low-frequency region 1, a high-frequency region 2, and a high-frequency region 1.

The degree to which the threshold values are varied between the low-frequency region and the high-frequency region is not particularly limited; however, even in measurement data for the high-frequency region, in a case where the magnitude of the body motion is too large, adjacent measurement data in the time domain may also be significantly affected by the body motion. Therefore, in a case where the threshold value for the low-frequency region is set to the reference threshold value set in advance as mentioned above, the threshold value for the high-frequency region may be set, for example, to about 1.5 to 2 times the threshold value for the low-frequency region. On the contrary, in a case where the threshold value for the high-frequency region is set as the reference threshold value, the threshold value for the low-frequency region may be set to about 0.8 to 0.5 times the threshold value for the high-frequency region. These ratios can be predetermined for each of the divided regions and applied based on the positions in k-space at the time of a determination process using the threshold value.

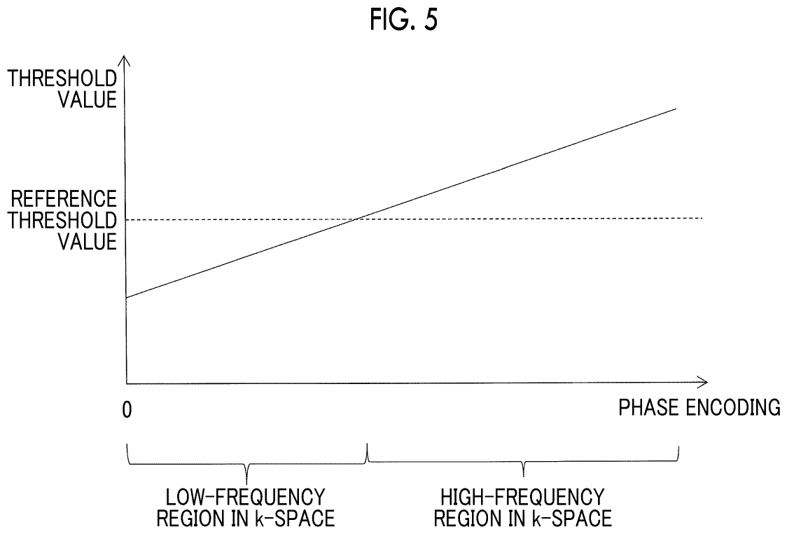

Note that instead of dividing k-space and applying threshold values, it is also possible to continuously change the threshold value from the low-frequency region to the high-frequency region, as shown in FIG. 5, for example. In FIG. 5, an example is shown in which the threshold value is linearly changed (using a linear function) with respect to the phase encoding, but a quadratic function or another type of function may also be used. In these cases, the function may be stored in a memory and read out during the determination process using the threshold value to perform the determination.

Note that the ratio by which the threshold value for body motion determination is varied between the low-frequency region and the high-frequency region, or a relationship between the threshold value and the phase encoding, may be set in advance, or can be set by the user via the UI unit 30 and used by the body motion processing unit 230.

Next, in a case where the main imaging is started, body motion information of the subject is acquired in parallel with the main imaging (S32). The method for acquiring the body motion information can be broadly classified into a method of acquiring the body motion information by analyzing frame images sent from the surveillance camera 80, and a method of acquiring the body motion information by analyzing nuclear magnetic resonance signals generated from the subject, for example, navigator echoes. Either method may be employed. Each of these methods is known, and detailed descriptions are omitted here. For example, in the analysis of frame images, body motion vectors for each pixel between frame images are calculated using methods such as optical flow, and the body motion amount is decided on. In addition, in the analysis of navigator echoes, there are methods such as generating and collecting nuclear magnetic resonance signals (navigator echoes) separately from the nuclear magnetic resonance signals collected in the main imaging, without applying phase encoding and acquiring positional changes in real space from data obtained by Fourier transforming the nuclear magnetic resonance signals in a one-dimensional direction, or analyzing changes in the navigator echoes themselves, may be used, and any of these methods may be employed.

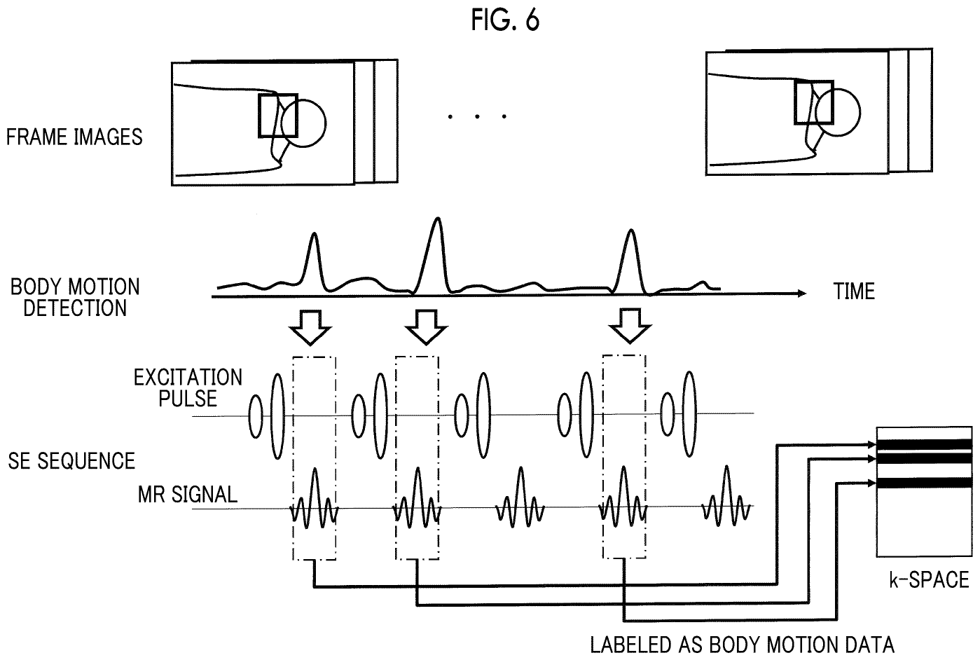

In a case where body motion is detected, the position in k-space of the measurement data collected at the time of body motion detection is acquired (S33). Since the position in k-space of the measurement data is determined by the phase encoding applied to the measurement data, the body motion processing unit 230 can obtain the position in k-space based on the progress of the pulse sequence. FIG. 6 shows a relationship between the body motion information and the pulse sequence. The example in FIG. 6 shows a case where the body motion processing unit 230 obtains the body motion information from frame images sent from the surveillance camera 80, and the pulse sequence is a spin echo (SE) type sequence.

Next, with reference to the position in k-space of the measurement data obtained in step S33 described above, it is determined whether or not the body motion that has occurred is body motion that affects the image by using a threshold value corresponding to the position in k-space (S34). As a result of the determination, in a case where the detected body motion exceeds the threshold value, as shown in FIG. 6, the measurement data in a case where the body motion occurs is labeled as the body motion-affected data.

The body motion processing unit 230 decides on the processing to be performed after body motion detection and during image reconstruction according to the continuity of the body motion, that is, the continuity of the specified body motion-affected data, the position in k-space of the body motion-affected data or the proportion occupied by the body motion-affected data in k-space, the imaging conditions, the image reconstruction conditions, and the like (S35). For example, in a case where a large amount of body motion-affected data occurs in the low-frequency region of k-space and significantly affects the image, the body motion-affected data may be re-captured. In such a case, the determination result is passed to the imaging control unit 210, and the imaging control unit 210 controls the pulse sequence so as to collect the specified body motion-affected data and the unmeasured data thereafter. In addition, in a case where the number of pieces of body motion-affected data is small and estimation by calculation is possible, imaging is continued as is, and a processing determination is made to perform predetermined body motion correction reconstruction during image reconstruction. It should be noted that the method of processing determination varies and is not limited to the methods mentioned above. For example, various known methods can be employed, such as adding a more detailed determination flow as disclosed in JP2023-022669A, or using criteria other than the position and number in k-space.

In a case where the body motion correction reconstruction is performed, the processing is the same as that shown in FIG. 3, and the body motion correction reconstruction (S36) and the display of the reconstructed image (S37) are performed.

The body motion correction reconstruction performed in a case where body motion-affected data is specified includes, for example, known methods such as: removing the body motion-affected data and performing zero substitution; correcting the phase of the body motion-affected data based on the magnitude of the body motion; estimating the body motion-affected data from other measurement data using Hermitian symmetry of k-space or by applying a parallel imaging (PI) method and performing image reconstruction; or performing iterative reconstruction in which the body motion-affected data is removed and estimated as unmeasured data through iterative calculation. Any of these methods can be employed.

As described above, in the present embodiment, in the body motion determination, the threshold value for body motion determination is varied according to the position in k-space of the measurement data collected at the time of body motion occurrence. As a result, it is possible to reduce excessive or insufficient specification of body motion-affected data, improve the accuracy of specifying the body motion-affected data, and improve the accuracy of subsequent body motion correction reconstruction.

### Embodiment of Body Motion Correction Reconstruction

Hereinafter, an embodiment of processing in a case where iterative calculation is used as the body motion correction reconstruction will be described.

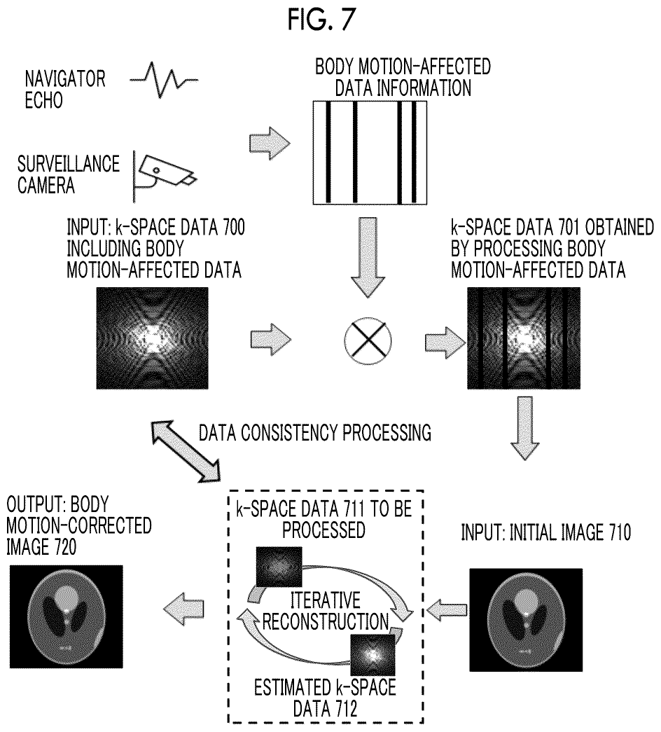

As shown in FIG. 7 as an example, in body motion correction by iterative calculation, measurement data 701 (image space data 710 thereof) obtained by removing body motion-affected data specified by body motion determination from measurement data 700 is used as an initial value, and estimation and interpolation of unmeasured data (data missing due to removal), transformation from the estimated measurement data 712 to image space data, and updating of the initial value are repeated. In this iterative calculation, an integration process (hereinafter, also referred to as data consistency processing) is performed to improve the consistency between the estimated measurement data 712 and the original measurement data 700, and a final body motion-corrected image 720 is generated.

Whereas body motion-affected data has been conventionally removed from the measurement data 700, in the present embodiment, a smoothing filter is applied to the body motion-affected data, and measurement data including the smoothed body motion-affected data is used. The measurement data including the smoothed body motion-affected data is inverse Fourier transformed into real space data, and the resulting image is used as an initial value (initial image) to perform the iterative calculation. Here, the smoothing filter is a one-dimensional filter in the frequency direction applied to the k-space data, and a blurring filter such as a Gaussian filter can be employed. In this case, the strength of the Gaussian filter may be varied according to the body motion level. That is, in a case where the body motion level is high, the filter strength is set higher, and in a case where the body motion level is low (for example, close to the threshold value), a standard filter strength is used.

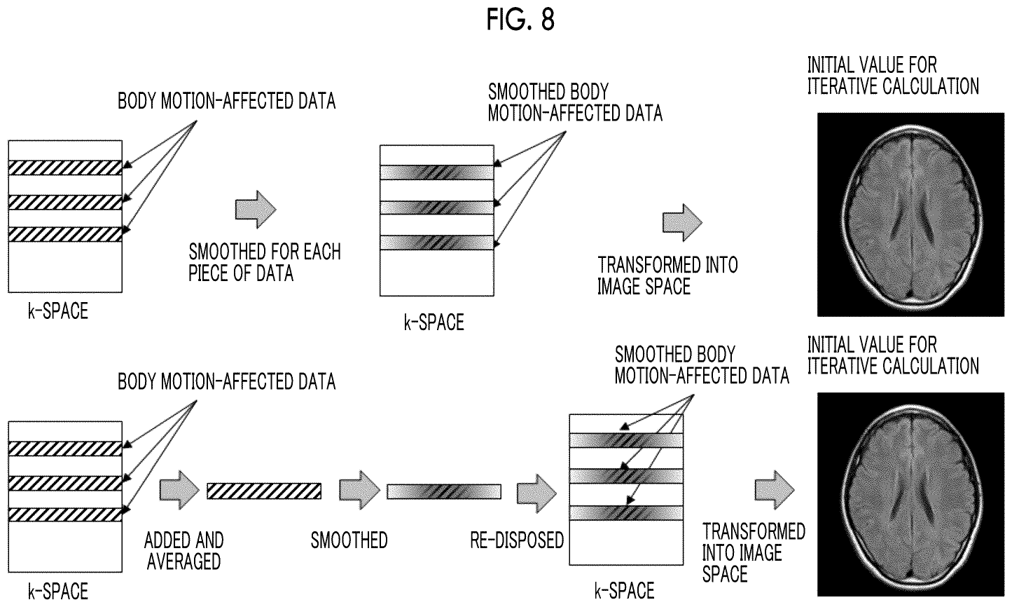

In a case where a plurality of pieces of body motion-affected data are present, either a method of smoothing each piece of body motion-affected data or a method of adding and smoothing the plurality of pieces of body motion-affected data may be employed. An example of the former is shown on the upper side of FIG. 8, and an example of the latter is shown on the lower side of FIG. 8. Here, as an example, it is assumed that three pieces of body motion-affected data are specified in the k-space data. As shown on the upper side of FIG. 8, in a case where each piece of body motion-affected data is smoothed, the above-mentioned one-dimensional filter is applied to each of the three pieces of body motion-affected data. In this case, the filter strength may be varied according to the distance of the body motion-affected data from the center of k-space (phase encoding 0). That is, the closer the body motion-affected data is to the center, the higher the filter strength is set, and the farther the body motion-affected data is from the center, the lower the filter strength is set.

In addition, as shown on the lower side of FIG. 8, in a case where a plurality of pieces of body motion-affected data are added and smoothed, an addition average of the plurality of pieces of body motion-affected data is first calculated, a one-dimensional filter is applied to the data after the addition average, and the data after the filtering process is then re-disposed to the original position of the body motion-affected data. In a case where the data after the addition average is re-disposed, a weight may be applied to the signal intensity according to the distance of the body motion-affected data from the center of k-space (phase encoding 0). Specifically, in a case where the data after the addition average and the smoothing process is re-disposed to the position of the body motion-affected data on the low-frequency region side, the signal intensity is weighted to be higher in accordance with the surrounding low-frequency region side data, and in a case where the data after the addition average and the smoothing process is re-disposed to the position of the body motion-affected data on the high-frequency region side, the signal intensity is weighted to be lower in accordance with the surrounding high-frequency region side data.

In addition, different weights may be applied to respective pieces of body motion-affected data in a case of performing the addition average, according to the distance from the center of k-space. For example, the weight of the measurement data in the high-frequency region may be set to be smaller, and the weight of the measurement data in the low-frequency region may be set to be larger. Alternatively, the weight may be varied according to the body motion level of the body motion-affected data. That is, the weight of the measurement data in a case where the body motion level acquired in body motion detection is high is set to be smaller, and the weight of the measurement data in a case where the body motion level is low is set to be relatively larger.

As mentioned above, by performing the filtering process on body motion-affected data that has been conventionally removed and using the body motion-affected data in body motion correction reconstruction, the initial image obtained by transforming the body motion-affected data after the filtering process, although containing the influence of body motion, includes more information on the original measurement data. Therefore, the calculation cost of the iterative calculation in body motion correction reconstruction can be reduced.

In addition, by performing the filtering process, it is possible to avoid re-capturing of body motion-affected data that has occurred in the low-frequency region, thereby preventing an increase in imaging time associated with re-capturing. Furthermore, in a case where a plurality of pieces of body motion-affected data are added and smoothed, a greater effect in reducing the calculation cost can be achieved by applying weighting corresponding to the magnitude of the influence of the body motion on the body motion-affected data, that is, weighting corresponding to the position in k-space or the body motion level.

The two methods mentioned above perform the filtering process on the body motion-affected data; however, as processing on the body motion-affected data, preliminary iterative calculation may be performed to perform data estimation. For example, iterative calculation for body motion correction is executed using only the collected body motion-affected data as the initial value. The k-space data obtained through this iterative calculation (the data corresponding to each piece of body motion-affected data) is added and averaged, restored to the original measurement data, and the result obtained by transforming it into image data is used as the initial value for the iterative calculation. In this method as well, by performing addition average, an effect of smoothing out positional shifts caused by body motion can be obtained in the same manner as in a case of re-disposing the data after the addition average and the smoothing process mentioned above, and there is an advantage that the body motion-affected data can be used without being removed. However, in order to suppress the increase in calculation cost caused by executing the preliminary iterative calculation, it is preferable to apply a high-intensity denoising process in the preliminary iterative calculation to accelerate convergence.

In the body motion correction reconstruction of the present embodiment, iterative calculation is performed using the initial image obtained after processing the body motion-affected data as mentioned above. As a result, it is possible to promptly obtain estimated k-space data with body motion correction while utilizing the information on the body motion-affected data.

The body motion correction reconstruction is performed in a form such as the example shown in FIG. 7, but in addition to using the initial image processed as mentioned above, a change that takes into account the k-space may also be made in the iterative calculation itself. However, this change is a change independent of the change of the initial image through the processing of the above-mentioned body motion-affected data itself, and it is not essential to apply both changes. In the body motion correction reconstruction, employing either one of the changes is also included in the body motion correction reconstruction of the present embodiment.

The iterative calculation repeatedly performs processing in which the k-space data (measurement data 701) obtained by transforming the initial image 710 is subjected to processing such as transformation into a sparse domain and L2 norm minimization to perform data estimation and obtain the estimated k-space data (estimated k-space data 712), and the initial image 710 is updated. In this case, processing (data consistency processing) is executed to maintain data consistency by integrating the estimated k-space data 712 obtained during the processing and the k-space data (pre-estimation k-space data 711) obtained by transforming the updated initial image with the original measurement data 700.

In the present embodiment, in the data consistency processing, weighting corresponding to the position in k-space where the body motion-affected data is present is applied to the k-space data 712 to be integrated. The weight is set to a weight that reflects at least one of the presence or absence of body motion or the magnitude of the body motion, and the weight of the data at a position where body motion has occurred or at a position where large body motion has occurred is increased to enhance the strength of the correction. That is, the weight of the data at the position in k-space where body motion-affected data has been specified is set to be larger than the weight of the data at the position in k-space position where no body motion-affected data is present. By applying such weighting, the correction strength for the influence of body motion in the estimated k-space data 712 can be enhanced, making it possible to obtain a final body motion-corrected image 720 with further reduced body motion, without causing image deterioration or a decrease in data consistency.

Weighting may be performed in consideration of the magnitude of the body motion itself instead of, or in addition to, the weight based on the position in k-space of the body motion-affected data. In such a case, a weight is assigned to the body motion-affected data according to the magnitude of the body motion at the time of the acquisition of each piece of body motion-affected data, and the k-space data is weighted in accordance with the weight such that data with a larger influence of body motion is given a larger weight, while data with a smaller influence or no influence of body motion is given a smaller weight.

In the data consistency processing, by applying the above-mentioned weighting to the k-space data 712 (a weight corresponding to the position in k-space of the body motion-affected data or a weight corresponding to the magnitude of the body motion), the effect of removing the influence of body motion, particularly the influence of large body motion, is strongly exerted within a single iteration (one iteration) of the iterative calculation. As a result, the effect of reducing the influence of body motion can be achieved even in a case where the number of iterations is limited.

As described above, according to the present embodiment, in body motion processing, by varying the threshold value for body motion determination according to the position in k-space of the nuclear magnetic resonance signal (measurement data) acquired at the time of body motion occurrence, it is possible to reduce excessive or insufficient body motion determination and perform highly accurate body motion determination.

According to the present embodiment, in a case where body motion correction reconstruction including iterative calculation is performed, image reconstruction is performed by performing processing of reducing the influence of body motion while utilizing the body motion-affected data as much as possible. The processing of reducing the influence of body motion includes, for example, smoothing the body motion-affected data and then using the smoothed body motion-affected data as the initial value for iterative calculation, and applying weighting corresponding to the position in k-space of the data collected at the time of body motion occurrence or the magnitude of the body motion, in the integration process for data consistency using data during the iterative calculation that includes the influence of body motion. By performing such processing, it is possible to reduce the calculation cost of the body motion correction reconstruction.

Note that the embodiment of threshold value setting for body motion determination and the embodiment related to the processing of body motion-affected data in body motion correction reconstruction in the present embodiment are independent of each other, and a combination of the embodiment of threshold value setting with other body motion correction reconstruction methods, and a combination of the embodiment related to body motion correction reconstruction with other threshold value setting methods, are also included in the present invention.

### Modification Example

In addition, in the above-described embodiment, a case has been described in which imaging and subsequent image reconstruction are performed as a series of processes. However, it is also possible to perform body motion correction reconstruction separately from the image reconstruction performed as part of the imaging, by specifying body motion-affected data based on body motion information (the magnitude of body motion and the time of body motion occurrence) associated with the measurement data after imaging. The present invention also includes such cases where body motion processing and/or body motion correction reconstruction is performed retrospectively. In such retrospective processing, a configuration may be employed in which the threshold value setting for body motion determination and the weight setting for body motion correction described in the embodiment mentioned above are set freely by the user.

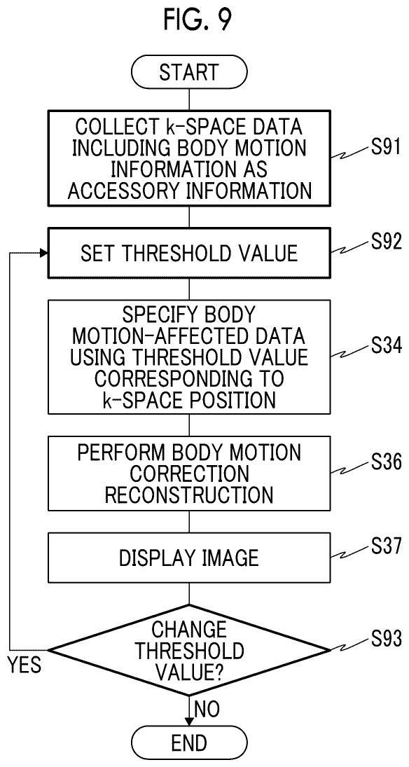

FIG. 9 shows a flow of processing in a case where the retrospective processing is performed. In FIG. 9, processing having the same content as that in FIG. 3 is indicated by the same reference numeral as in FIG. 3, and overlapping descriptions are omitted. In a case where image reconstruction is performed retrospectively, k-space data associated with body motion information is first acquired (S91). In this k-space data, information indicating that the k-space data has been acquired at the time of body motion occurrence, and the body motion level at that time, are labeled as accessory information. In a case where the user sets a desired threshold value (S92), the body motion processing unit 230 specifies the body motion-affected data by using the threshold value (S34). The threshold value set by the user may be a single threshold value, but threshold values corresponding to the positions in k-space, for example, different threshold values for the low-frequency region and the high-frequency region, are set. The method is the same as that in the embodiment of the threshold value mentioned above. After that, predetermined processing, for example, a filtering process, is applied to the specified body motion-affected data, body motion correction reconstruction including iterative calculation is performed, and the generated image is displayed (S36, S37). The user performs body motion correction reconstruction by changing, as necessary, the manner in which the threshold values for the low-frequency region and the high-frequency region are varied (S93).

Note that although FIG. 9 shows a case where only the threshold value is set by the user, it is also possible to employ a configuration in which the user sets conditions for body motion correction reconstruction, for example, the selection of the filtering method or the weight in data consistency processing.

According to the present modification example, it is possible to generate various body motion-corrected images under different body motion processing conditions, and the user can decide on the optimal condition for body motion processing.

### EXPLANATION OF REFERENCES

1: MRI apparatus
10: imaging unit
20: processor
30: UI unit
50: subject
230: body motion processing unit

What is claimed is:

1. A magnetic resonance imaging apparatus comprising:
an imaging unit configured to collect k-space data comprising magnetic resonance signals; and
a processor configured to generate an image using the k-space data and analyze body motion of a subject during imaging,
wherein the processor is configured to:
detect the body motion of the subject during imaging by using information from an optical imaging device that optically images the subject during imaging or the magnetic resonance signals obtained by the imaging unit; and
specify, in the k-space data, data affected by the body motion as body motion-affected data,
wherein the processor is further configured to:
vary, during the specification, a threshold value used to specify the body-motion affected data, depending on a position in k-space of the data.

2. The magnetic resonance imaging apparatus according to claim 1,
wherein the processor is configured to set the threshold value to be lower on a low-frequency region side of the k-space and to be higher on a high-frequency region side of the k-space.

3. The magnetic resonance imaging apparatus according to claim 2,
wherein the processor is configured to divide the k-space into a plurality of regions including a low-frequency region and a high-frequency region, and set a threshold value to be applied to data in the low-frequency region to be lower than a threshold value to be applied to data in the high-frequency region.

4. The magnetic resonance imaging apparatus according to claim 1,
wherein the processor is configured to generate a body motion-corrected image in which the body motion is corrected by performing iterative calculation using the k-space data including the body motion-affected data.

5. The magnetic resonance imaging apparatus according to claim 4,
wherein the processor is configured to generate the body motion-corrected image by substituting the body motion-affected data with zero.

6. The magnetic resonance imaging apparatus according to claim 4,
wherein the processor is configured to perform a smoothing process on the body motion-affected data, and generate the body motion-corrected image using the k-space data including the smoothed body motion-affected data.

7. The magnetic resonance imaging apparatus according to claim 4,
wherein the processor is configured to, in a case where the k-space data includes a plurality of pieces of the body motion-affected data, perform a smoothing process after adding the plurality of pieces of body motion-affected data, re-dispose the smoothed pieces of body motion-affected data to original positions in k-space of the plurality of pieces of body motion-affected data, and then generate the body motion-corrected image.

8. The magnetic resonance imaging apparatus according to claim 4,
wherein the iterative calculation includes a transformation from k-space data to image space data, a data estimation process in image space, a transformation from the estimated image space data to k-space data, an integration process performed as data consistency processing to match data between k-space data during the calculation and actually measured data, and a transformation from the k-space data after the integration process to image space data, and
a weight of the k-space data during the calculation in the integration process is varied according to the position in k-space of the body motion-affected data.

9. A magnetic resonance imaging apparatus comprising:
an imaging unit configured to collect k-space data consisting of magnetic resonance signals; and
a processor configured to generate an image by using the k-space data and analyze body motion of a subject during imaging,
wherein the processor is configured to:
detect the body motion of the subject during imaging by using information from an optical imaging device that optically images the subject during imaging or the magnetic resonance signals obtained by the imaging unit;
specify, in the k-space data, data affected by the body motion as body motion-affected data, and perform body motion correction reconstruction including iterative calculation by using the k-space data including the body motion-affected data; and
perform processing of reducing an influence of the body motion on the body motion-affected data in the body motion correction reconstruction.

10. An image generating apparatus configured to generate a magnetic resonance image with body motion correction by using k-space data acquired by a magnetic resonance imaging apparatus, the k-space data including, as accessory information, body motion information in a case where the k-space data is acquired, the image generation apparatus comprising a processor configured to:
specify, in the k-space data, data affected by body motion as body motion-affected data, and perform body motion correction reconstruction including iterative calculation by using the k-space data including the body motion-affected data; and
during the body motion correction reconstruction, perform a smoothing process on the body motion-affected data, and then using, as an initial value of the iterative calculation, an image obtained by transforming, into image space, the k-space data including the body motion-affected data after the smoothing process.

11. The image generation apparatus according to claim 10,
wherein the iterative calculation includes a transformation from k-space data to image space data, a data estimation process in image space, a transformation from the estimated image space data to k-space data, an integration process performed as data consistency processing to match data between k-space data during the calculation and actually measured data, and a transformation from the integrated k-space data to image space data, and
a weight of the k-space data during the calculation in the integration process is varied according to a position in k-space of the body motion-affected data.
